(19) United States
(12) Patent Application Publication
(10) Pub. No.: US 2014/0252400 A1
(43) Pub. Date: Sep. 11, 2014

(54) LIGHT EMITTING DEVICE

(71) Applicants: Cheng-Yen Chen, Tainan City (TW); Sheng-Yuan Sun, Tainan City (TW); Chih-Ming Chen, Tainan City (TW); Yi-Hao Huang, Tainan City (TW); Kuan-Wen Chen, Tainan City (TW)

(72) Inventors: Cheng-Yen Chen, Tainan City (TW); Sheng-Yuan Sun, Tainan City (TW); Chih-Ming Chen, Tainan City (TW); Yi-Hao Huang, Tainan City (TW); Kuan-Wen Chen, Tainan City (TW)

(73) Assignee: GENESIS PHOTONICS INC., Tainan City (TW)

(21) Appl. No.: 13/971,845

(22) Filed: Aug. 21, 2013

(30) Foreign Application Priority Data
Mar. 6, 2013 (TW) 102107922

(51) Int. Cl. H01L 33/48

(52) U.S. Cl. CPC H01L 33/48
USPC 257/99

(57) ABSTRACT

A light emitting device including a carrier, a substrate, at least one electrode pair, at least one light emitting diode (LED) and at least one positioning element is provided. The substrate is disposed on the carrier and has a body portion and at least one bending portion. The bending portion connects to the body portion. The bending portion is not coplanar with the body portion. The electrode pair is located on the body portion of the substrate. The LED is disposed on the body portion of the substrate and electrically connected to the electrode pair. The positioning element is disposed on the bending portion of the substrate for fixing the substrate on the carrier.

### CROSS-REFERENCE TO RELATED APPLICATION

This application claims the priority benefit of Taiwan application serial no. 102107922, filed on Mar. 6, 2013. The entirety of the above-mentioned patent application is hereby incorporated by reference herein and made a part of this specification.

### BACKGROUND OF THE INVENTION

1. Field of the Invention

The invention relates to a light emitting device, and more particularly, to a light emitting device using a light emitting diode chip as light source.

2. Description of Related Art

General lighting that use light emitting diodes are all disposing locking screws used for positioning and electrode pairs electrically connected to the light emitting diodes on a substrate at a same plane. As current products all trending toward design requirements of being light, thin, short and small, distances between the screws and the electrode pairs are also shortened. Since the screws are generally made of metal materials and have conductivity, as a result, when the lightings are performing a high pressure test, conditions such as an arcing effect, a short-circuit, a broken circuit or current leakage can easily occur between the locking screws and the electrode pairs. The above phenomenon is not only unable to comply with requirements of a security specification standard certification (simply referred to as a safety regulation), but also causes security concerns at the time of use. Therefore, the conventional light emitting diode lightings still have a larger room for improvement.

### SUMMARY OF THE INVENTION

The invention provides a light emitting device capable of avoiding an arcing effect so as to better comply with safety regulations.

The light emitting device of the invention includes a carrier, a substrate, at least one electrode pair, at least one light emitting diode and at least one positioning element. The substrate is disposed on the carrier and has a body portion and at least one bending portion. The bending portion connects the body portion and is not coplanar with the body portion. The electrode pair is disposed on the body portion of the substrate. The light emitting diode is disposed on the body portion of the substrate and electrically connects to the electrode pair. The positioning element is disposed on the bending portion of the substrate so as to fix the substrate on the carrier.

In an embodiment of the invention, the carrier includes a heat dissipation block, a heat dissipation fin, a heat dissipation plate body, a thermal conductive column or a heat pipe.

In an embodiment of the invention, the body portion and the bending portion of the substrate have an included angle therebetween, and the included angle is ranged from 30 degrees to 150 degrees.

In an embodiment of the invention, an area of the body portion of the substrate is 1.05 times to 1.3 times of an area of the light emitting diode.

In an embodiment of the invention, the light emitting device further includes a mask disposed on the body portion of the substrate and covering the light emitting diode and the electrode pair.

In an embodiment of the invention, the mask includes a fluorescent conversion mask or a lens.

In an embodiment of the invention, an orthogonal projection area of the mask on the body portion of the substrate is equal to or larger than a surface area of the body portion of the substrate.

In an embodiment of the invention, a maximum distance between two points in an opening of the mask equals to a maximum distance between two points at edges of the body portion of the substrate.

In an embodiment of the invention, the carrier includes at least one first positioning hole, and the substrate includes at least one second positioning hole. The second positioning hole is located on the bending portion. The positioning element passes through the second positioning hole and the first positioning hole so as to fix the substrate on the carrier.

In an embodiment of the invention, the positioning element includes a screw, a bolt or a rivet.

In an embodiment of the invention, the first positioning hole includes a screw hole, a through hole or a blind hole.

In an embodiment of the invention, the second positioning hole includes a screw hole, a through hole or a blind hole.

According to the foregoing, through designing the body portion and the bending portion of the substrate to be not coplanar with each other, the invention can effectively isolate the positioning element from the electrode pair electrically connected with the light emitting diode. As a result, the area of the substrate dose not have to be increase and the distance between the positioning element and the electrode pair can be increased, so as to prevent the arcing effect from being generated due to a mutual induction thereof and avoid a short-circuit from occurring, thereby increasing a number of times of passing a high pressure resistance test, as well as better complying with safety regulations.

In order to make the aforementioned and other features and advantages of the present application more comprehensible, several embodiments accompanied with figures are described in detail below.

### BRIEF DESCRIPTION OF THE DRAWINGS

The accompanying drawings are included to provide a further understanding of the application, and are incorporated in and constitute a part of this specification. The drawings illustrate embodiments of the application and, together with the description, serve to explain the principles of the application.

FIG. 1 is a top view schematically illustrating a light emitting device according to an embodiment of the invention.

FIG. 2 is a cross-sectional view schematically illustrating the light emitting device of FIG. 1.

FIG. 3 is a top view schematically illustrating a substrate according to an embodiment of the invention.

FIG. 4 is a cross-sectional view schematically illustrating a substrate according to another embodiment of the invention.

### DETAILED DESCRIPTION OF DISCLOSED EMBODIMENTS

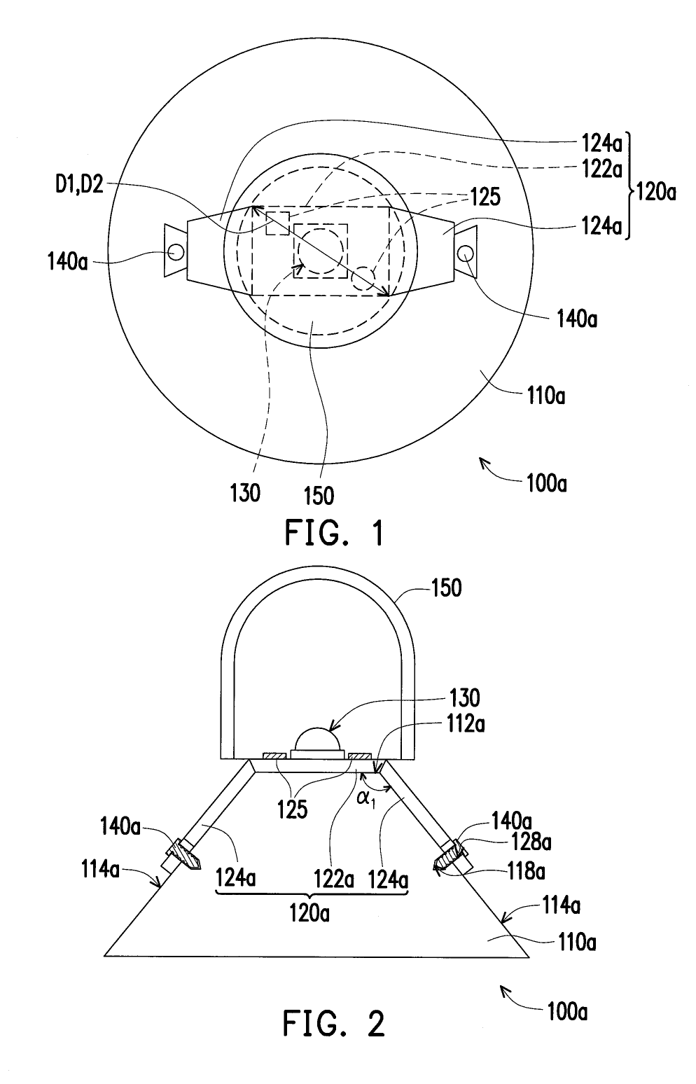

FIG. 1 is a top view schematically illustrating a light emitting device according to an embodiment of the invention. FIG. 2 is a cross-sectional view schematically illustrating the light emitting device of FIG. 1. Referring to FIG. 1 and FIG. 2, in the present embodiment, a light emitting device 100a includes a carrier 110a, a substrate 120a, at least one electrode pair 125 (one pair is schematically illustrated in FIG. 1 and FIG. 2), at least one light emitting diode 130 (one is schematically illustrated in FIG. 1 and FIG. 2) and at least one positioning element 140a (two are schematically illustrated in FIG. 1 and FIG. 2).

In detail, the substrate 120a is disposed on the carrier 110a and has a body portion 122a and at least one bending portion 124a (two are schematically illustrated in FIG. 1), wherein the bending portions 124a connect the body portion 122a. Specifically, the bending portions 124a and the body portion 122a are not coplanar. The electrode pair 125 is disposed on the body portion 122a of the substrate 120. The light emitting diode 130 is disposed on the body portion 122a of the substrate 120a and electrically connected to the electrode pair 125. The positioning elements 140a are disposed on the bending portions 124a of the substrate 120a, so as to fix the substrate 120a on the carrier 110a.

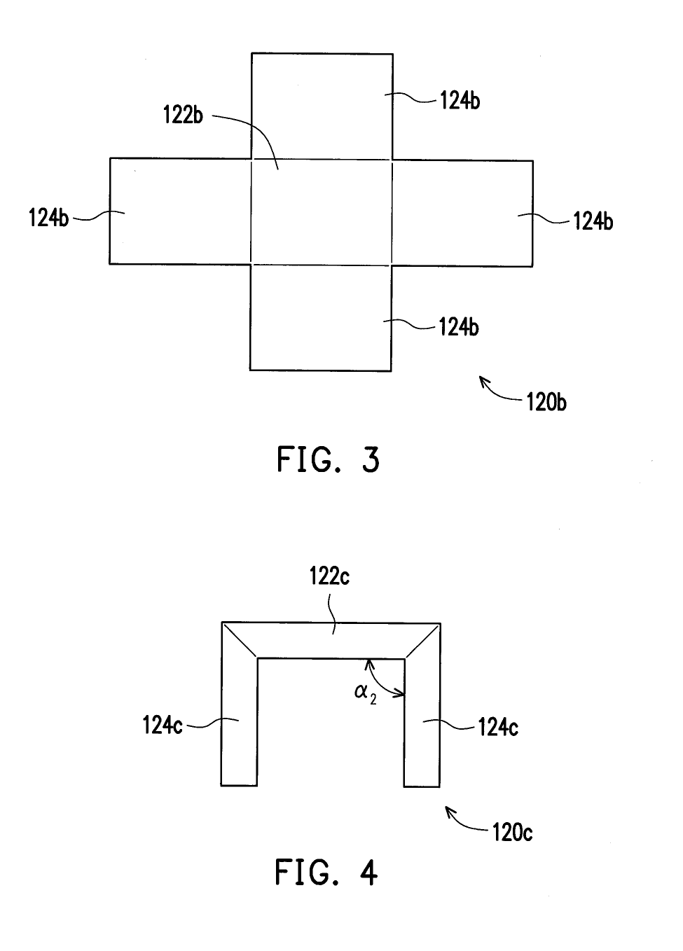

More specifically, the carrier 110a of the present embodiment, for example, is a heat dissipation block made with a good thermal conductive material, such as copper, aluminum or ceramic. The substrate 120a, for example, is a flexible substrate, wherein the body portion 122a of the substrate 120a is disposed on a top surface 112a of the carrier 110a, and the bending portions 124a of the substrate 120a are disposed on a side surface 114a of the carrier 110a that is connected to the top surface 112a. As shown in FIG. 1, an appearance of the substrate 120a, for example, is a belt-shape. Certainly, in other embodiment, referring to FIG. 3, an appearance of a substrate 120b may also be a cruciform, namely, the substrate 120b has four bending portions 124b connected to the body portion 122b, and this still counts as an adoptable technical solution of the invention and not departing from the desired scope of protection of the invention.

As shown in FIG. 2, the body portion 122a and each of the bending portions 124a of the substrate 120a of the present embodiment have an included angle α1 therebetween, and the included angle α1 is ranged from 90 degrees to 150 degrees. In other embodiment, referring to FIG. 4, the body portion 122c and each of the bending portions 124c of the substrate 120c have an included angle α2 therebetween, wherein the included angle α2 is 90 degrees, and this design further has an effect of enabling a larger light emitting angle; alternately, in other embodiment not shown by drawings, the included angle between the body portion and the bending portion of the substrate may be smaller than 90 degrees, but in considerations for a circuit design and heat dissipating effect, a favorable included angle is preferred not to be less than 30 degrees. More specifically, the included angle between the body portion 122a and each of the bending portions 124a of the substrate 120a is preferably ranged from 30 degrees to 150 degrees. Moreover, since the positioning elements 140a are disposed on the bending portions 124a of the substrate 120a, the body portion 122a may reduce an area that is reserved for a locking screw in a conventional light emitting, such that an overall area and volume of the light emitting device 100a may also be reduced and thereby having a flexible configuration space. More preferably, the area of body portion 122a is 1.05 times to 1.3 times of the area of the light emitting diode 130. The above techniques still counts as an adoptable technical solution of the invention and not departing from the desired scope of protection of the invention.

Furthermore, the carrier 110a of the present embodiment includes at least one first positioning hole 118a (two are schematically illustrated in FIG. 2), and the substrate 120a includes at least one second positioning hole 128a (two are schematically illustrated in FIG. 2). The second positioning holes 128a are located on the bending portions 124a. The positioning elements 140a pass through the second positioning holes 128a and the first positioning holes 118a, so as to fix the substrate 120a on the carrier 110a. Herein, the positioning elements 140a, for example, are screws, and the first positioning holes 118a and the second positioning holes 128a, for example, are all screw holes.

In addition, the light emitting device 100a of the present embodiment may further include a mask 150, wherein the mask 150 is disposed on the body portion 122a of the substrate 120a and covers the light emitting diode 130 and the electrode pair 125. The mask 150, for example, is a fluorescent conversion mask being used for and capable of converting wavelengths of a portion of light emitted by the light emitting diode 130. Herein, as shown in FIG. 1, an orthogonal projection area of the mask 150 on the body portion 122a of the substrate 120a is larger than a surface area of the body portion 122a of the substrate 120a. Certainly, in other embodiment (not shown), the orthogonal projection area of the mask 150 on the body portion 122a of the substrate 120a may also be equal to the surface area of the body portion 122a of the substrate 120a. In addition, a maximum distance D1 between two points in an opening of the mask 150 equals to a maximum distance between two points at edges of the body portion 122a of the substrate 120a. Herein, the maximum distance between the two points at the edges of the body portion 122a of the substrate 120a is a diagonal length D2 of the body portion 122a.

Since the body portion 122a and the bending portions 124a of the substrate 120a of the present embodiment are not coplanar, when the positioning elements 140a lock the carrier 110a and the substrate 120a, as compared to the conventional electrode pair and the locking screw being at a same plane, a distance between the electrode pair 125 and the positioning elements 140a of the present embodiment may be effectively increased. Namely, the positioning elements 140a are effectively isolated from the electrode pair 125 electrically connected to the light emitting diode 130. As a result, an arcing effect generated due to a mutual induction between the electrode pair 125 and the positioning elements 140a may be prevented, and a short-circuit may be avoided, thereby increasing a number of times that the light emitting device 100a of the present embodiment passes a high pressure resistance test, as well as better complying with safety regulations. In addition, heat outputted by the light emitting diode 130 of the present embodiment may also be transferred to the bending portions 124a via a design of the substrate 120a, and then through a conduction of the carrier 110a, avoided from accumulating on the body portion 122a, so as to effectively enhance a heat dissipation effect of the light emitting device 100a.

Noteworthy, the invention does not intended to limit the shape of the carrier 110a, even though the aforesaid carrier 110a, herein, is embodied as a trapezoidal heat dissipation block. However, in other embodiment (not shown), the carrier 110a may also be a heat dissipation fin, a heat dissipation plate body, a thermal conductive column or a heat pipe, and is still counted as an adoptable technical solution of the invention and not departed from the desired scope of protection of the invention. Furthermore, the invention also does not intended to limit the structural shapes of the first positioning holes 118a, the second positioning holes 128a and the positioning elements 140, even though the aforesaid first positioning holes 118a, second positioning holes 128a and positioning elements 140, herein, are respectively embodied as screw holes, screw holes and screws. However, in other embodiment (not shown), the first positioning holes 118a and the second positioning holes 128a may also be a combination of two of the following three: screw holes, through holes and blind holes, and the positioning elements 140 may also be bolts or rivets. Alternately, since the body portion 122a and the bending portions 124a of the substrate 120a are not coplanar, under a condition of not limited by a safety distance with the electrode pair 125 and the surface area of the substrate 120a, the positioning element 140a is provided with a more flexible fixing method. In more detail, the positioning elements 140a, in addition to fixing the substrate 120a on the carrier 110a via a screw locking method, may also fix the substrate 120a on the carrier 110a via a snapping or latching method; those skilled in the art would be able to refer to the above descriptions of the embodiments and accord to actual needs to achieve a technical effect of fixing the carrier 110a and the substrate 120a. Moreover, in other embodiment (not shown), the mask 150 may also be a lens with a light transmittance, and this counts as an adoptable technical solution of the invention and not departing from the desired scope of protection of the invention.

In summary, through designing the body portion and the bending portion of the substrate to be not coplanar with each other, the invention can effectively isolate the positioning element from the electrode pair electrically connected with the light emitting diode. As a result, the distance between the positioning element and the electrode pair may be increased, so as to prevent the arcing effect from being generated due to the mutual induction thereof and avoid a short-circuit from occurring, thereby increasing the number of times of passing the high pressure resistance test, as well as better complying with safety regulations. In addition, the heat outputted by the light emitting diode of the invention may also be transferred to the bending portion through the design of the substrate, so as to avoid the heat from being accumulated on the body portion, and thereby effectively enhance the heat dissipation effect of the light emitting device.

It will be apparent to those skilled in the art that various modifications and variations can be made to the structure of the application without departing from the scope or spirit of the application. In view of the foregoing, it is intended that the application cover modifications and variations of this application provided they fall within the scope of the following claims and their equivalents.

What is claimed is:

1. A light emitting device comprising:
a carrier;
a substrate disposed on the carrier and having a body portion and at least one bending portion, wherein the bending portion connects to the body portion, and the bending portion is not coplanar with the body portion;
at least one electrode pair disposed on the body portion of the substrate;
at least one light emitting diode disposed on the body portion of the substrate and electrically connected to the electrode pair; and
at least one positioning element disposed on the bending portion of the substrate so as to fix the substrate on the carrier.

2. The light emitting device as recited in claim 1, wherein the carrier comprises a heat dissipation block, a heat dissipation fin, a heat dissipation plate body, a thermal conductive column or a heat pipe.

3. The light emitting device as recited in claim 1, wherein the body portion and the bending portion of the substrate have an included angle therebetween, and the included angle is ranged from 30 degrees to 150 degrees.

4. The light emitting device as recited in claim 1, wherein an area of the body portion of the substrate is 1.05 times to 1.3 times of an area of the light emitting diode.

5. The light emitting device as recited in claim 1 further comprising:
a mask disposed on the body portion of the substrate and covering the light emitting diode and the electrode pair.

6. The light emitting device as recited in claim 5, wherein the mask comprises a fluorescent conversion mask or a lens.

7. The light emitting device as recited in claim 5, wherein an orthogonal projection area of the mask on the body portion of the substrate is equal to or larger than a surface area of the body portion of the substrate.

8. The light emitting device as recited in claim 5, wherein a maximum distance between two points in an opening of the mask equals to a maximum distance between two points at edges of the body portion of the substrate.

9. The light emitting device as recited in claim 1, wherein the carrier comprises at least one first positioning hole, the substrate comprises at least one second positioning hole, the second positioning hole is located on the bending portion, and the positioning element passes through the second positioning hole and the first positioning hole so as to fix the substrate on the carrier.

10. The light emitting device as recited in claim 9, wherein the positioning element comprises a screw, a bolt or a rivet.

11. The light emitting device as recited in claim 9, wherein the first positioning hole comprises a screw hole, a through hole or a blind hole.

12. The light emitting device as recited in claim 9, wherein the second positioning hole comprises a screw hole, a through hole or a blind hole.
